(19) United States
(12) Patent Application Publication
(10) Pub. No.: US 2015/0028485 A1
(43) Pub. Date: Jan. 29, 2015

(54) SUBSTRATE STRUCTURE AND SEMICONDUCTOR PACKAGE HAVING THE SAME

(71) Applicant: Siliconware Precision Industries Co., Ltd., Taichung (TW)

(72) Inventors: Liang-Yi Hung, Taichung Hsien (TW); Shih-Chao Chih, Taichung Hsien (TW); Yu-Cheng Pai, Taichung Hsien (TW); Wei-Chung Hsiao, Taichung Hsien (TW)

(73) Assignee: SILICONWARE PRECISION INDUSTRIES CO., LTD., Taichung (TW)

(21) Appl. No.: 13/950,638

(22) Filed: Jul. 25, 2013

(51) Int. Cl. H01L 23/48

(52) U.S. Cl. CPC H01L 23/48
USPC 257/773

(57) ABSTRACT

A substrate structure is provided. The substrate structure includes a substrate body; a metal layer formed on a surface of the substrate body; an insulating layer formed on the surface of the substrate body and having at least an opening for exposing the metal layer; and at least a die attach area defined on the surface of the substrate body corresponding in position to the opening for a semiconductor chip to be disposed thereon. The die attach area covers the entire opening or the metal layer is formed within the die attach area, thereby effectively preventing package delamination and improving the product yield.

### BACKGROUND OF THE INVENTION

1. Field of the Invention

The present invention relates to substrate structures and semiconductor packages, and more particularly, to a substrate structure and a semiconductor package for flip-chip packaging.

2. Description of Related Art

There are two types of flip-chip packages: FCBGA packages and FCCSP packages. A packaging substrate used for a FCBGA package is usually big and thick so as to have high rigidity. Such a packaging substrate is mostly used for carrying CPUs and GPUs. Referring to FIG. 1, to form a FCBGA package, a semiconductor chip 11 is disposed on a packaging substrate 10, and then an underfill 12 is filled between the semiconductor chip 11 and the packaging substrate 10 through a capillary underfill (CUF) process so as to protect solder balls 13. Further, an inactive surface 111 of the semiconductor chip 11 is exposed so as for a heat dissipation member (not shown) to be disposed thereon.

FIG. 2A shows a cross-sectional view of a conventional FCCSP package, and FIG. 2B shows a top view of a packaging substrate 20 used in the FCCSP package. The packaging substrate 20 is usually small and thin and mostly used in portable electronic products. Generally, through molded underfill (MUF) technology, an encapsulant 22 is filled between the semiconductor chip 21 and the packaging substrate 20, and completely encapsulates the semiconductor chip 21, thereby dispensing with an additional process to form an underfill between the semiconductor chip 21 and the packaging substrate 20 as in a FCBGA package so as to save time and cost. The encapsulant 22 has a high rigidity, which prevents warpage of the overall package structure and increases the product reliability.

In some cases, a copper layer 201 in a central region of the packaging substrate 20 is partially exposed from an insulating layer 23 for heat dissipation, electrical conduction or grounding.

However, since large stresses are generated at edges A of the projection of the semiconductor chip 21 on the copper layer 201, delamination easily occurs between the encapsulant 22 and the copper layer 201 during a temperature reliability test, thus resulting in failure of the reliability test.

Therefore, how to overcome the above-described drawbacks has become critical.

### SUMMARY OF THE INVENTION

In view of the above-described drawbacks, the present invention provides a substrate structure, which comprises: a substrate body; a metal layer formed on a surface of the substrate body; an insulating layer formed on the surface of the substrate body and having at least an opening exposing the metal layer; and at least a die attach area defined on the surface of the substrate body corresponding in position to the opening for a semiconductor chip to be disposed thereon, wherein the die attach area extends over the entire opening or the metal layer is formed within the die attach area.

The present invention further provides a semiconductor package, which comprises: a substrate body; a metal layer formed on a surface of the substrate body; an insulating layer formed on the surface of the substrate body and having at least an opening exposing the metal layer; and at least a semiconductor chip disposed on the metal layer corresponding in position to the opening, wherein the projection of the semiconductor chip on the surface of the substrate body covers the entire opening or the metal layer is formed within the range of the projection of the semiconductor chip on the surface of the substrate body.

Therefore, since the metal layer is not exposed at edges of the projection of the semiconductor chip on the surface of the substrate body and the total exposed area of the metal layer is reduced, when an encapsulant is subsequently formed on the metal layer, the present invention effectively prevents delamination from occurring between the encapsulant and the metal layer due to a heterojunction interface between the encapsulant and the metal layer, thereby improving the product yield.

### BRIEF DESCRIPTION OF DRAWINGS

FIG. 1 is a cross-sectional view showing a conventional FCBGA package;

FIGS. 2A and 2B show cross-sectional views of a conventional FCCSP package and a schematic top view of a packaging substrate used in the FCCSP package, respectively;

FIG. 3 is a cross-sectional view showing a substrate structure and a semiconductor package according to a first embodiment of the present invention; and

FIG. 4 is a cross-sectional view showing a substrate structure and a semiconductor package according to a second embodiment of the present invention.

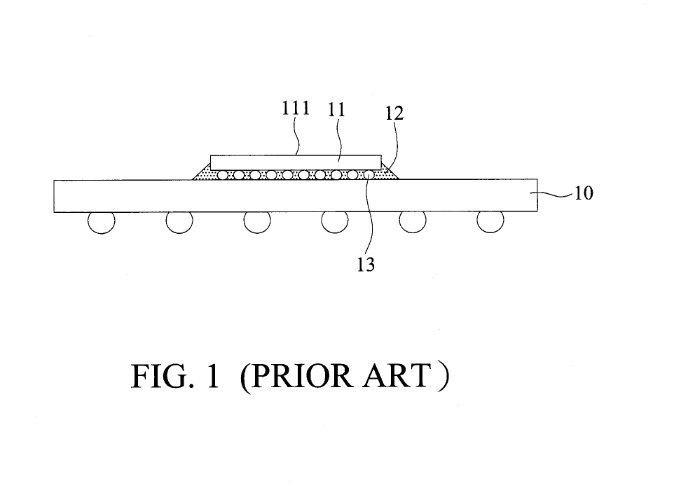

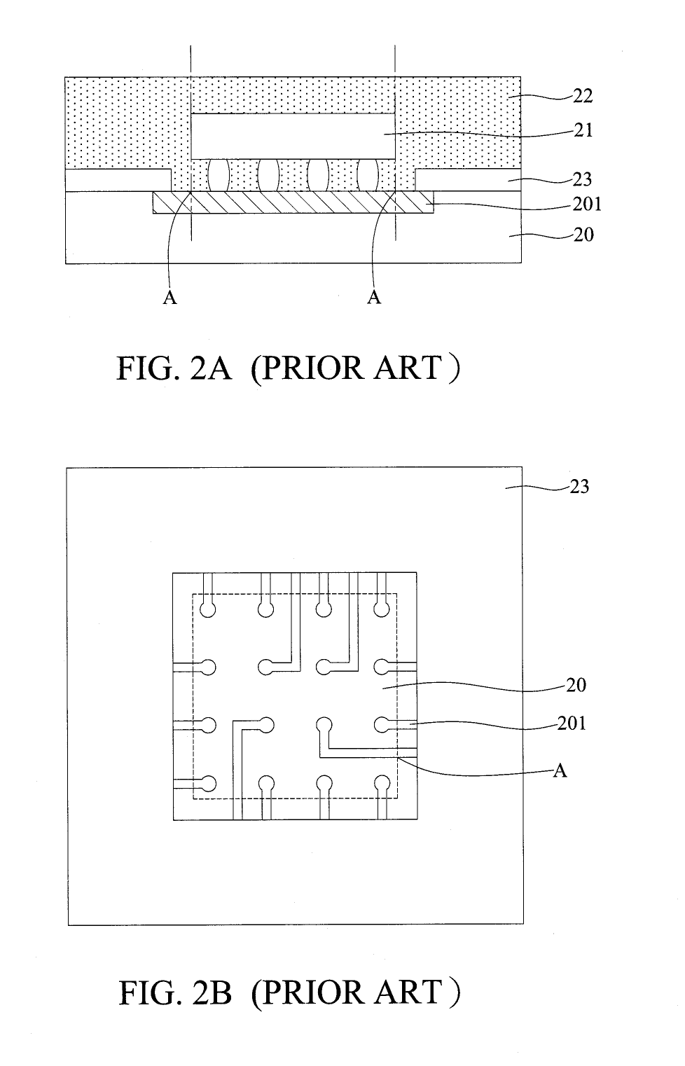

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that the drawings are only for illustrative purposes and not intended to limit the present invention. Meanwhile, terms, such as “upper”, “center”, “a” etc., are only used as a matter of descriptive convenience and not intended to have any other significance or provide limitations for the present invention.

### First Embodiment

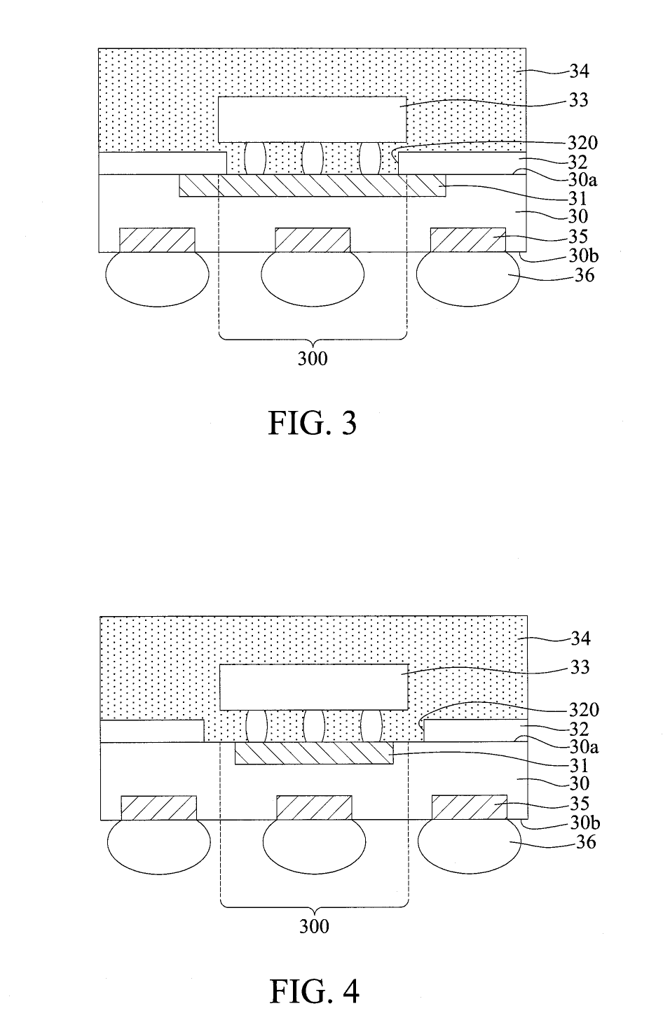

FIG. 3 shows a substrate structure and a semiconductor package according to a first embodiment of the present invention. The substrate structure has a substrate body 30; a metal layer 31 formed on a surface 30a of the substrate body 30; an insulating layer 32 formed on the surface 30a of the substrate body 30 and having an opening 320 exposing a portion of the metal layer 31; and a die attach area 300 defined on the surface 30a of the substrate body 30 corresponding in position to the opening 320 for a semiconductor chip 33 to be disposed thereon, wherein the die attach area 300 extends over the entire opening 320 and is preferably located at the center of the opening 320. In an embodiment, the substrate body 30 is made of ABF (Ajinomoto Build-up Film), BCB (Benzocyclobutene), LCP (liquid crystal polymer), PI (polyimide), PPE (polyphenylene ether), PTFE (polytetrafluoroethylene), FR4, FR5, BT (Bismaleimide Triazine), aramide or a mixture of epoxy resin and glass fiber, and the insulating layer 32 is made of solder-resist green paint.

In an embodiment, the semiconductor chip 33 is disposed on the die attach area 300 and located at the center of the opening 320, and the projection of the semiconductor chip 33 on the surface 30a of the substrate body 30 covers the entire opening 320 and the planar size of the semiconductor chip 33 is larger than the size of the opening 320.

In an embodiment, the package further has an encapsulant 34 formed on the surface 30a of the substrate body 30 for encapsulating the semiconductor chip 33.

In an embodiment, the semiconductor chip 33 is disposed on the metal layer 31 in a flip-chip manner, and the metal layer 31 is made of copper.

In an embodiment, the other surface 30b of the substrate body 30 has a plurality of conductive pads 35 so as for a plurality of solder balls 36 to be formed thereon.

### Second Embodiment

FIG. 4 is a cross-sectional view showing a substrate structure and a semiconductor package according to a second embodiment of the present invention. The substrate structure has a substrate body 30; a metal layer 31 formed on a surface 30a of the substrate body 30; an insulating layer 32 formed on the surface 30a of the substrate body 30 and having an opening 320 exposing the metal layer 31; and a die attach area 300 defined on the surface 30a of the substrate body 30 for a semiconductor chip 33 to be disposed thereon, wherein the metal layer 31 is formed within the die attach area 300. Preferably, the die attach area 300 is located at the center of the opening 320.

In an embodiment, the semiconductor chip 33 is disposed on the die attach area 300 and located at the center of the opening 320, and the metal layer 31 is formed within the range of the projection of the semiconductor chip 33 on the surface 30a of the substrate body 30.

Other features of the present embodiment are similar to the first embodiment, and detailed description thereof is hereby omitted.

In an embodiment, a dielectric layer (not shown) formed on the surface of the substrate body 30 is exposed from the opening 320, and the metal layer 31 further has circuits (not shown) and heat dissipation pads (not shown).

Therefore, since the metal layer is not exposed at edges of the projection of the semiconductor chip on the surface of the substrate body and the total exposed area of the metal layer is reduced, when an encapsulant is subsequently formed on the metal layer, the present invention can effectively prevent delamination from occurring between the encapsulant and the metal layer due to a heterojunction interface between the encapsulant and the metal layer, thereby improving the product yield.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A substrate structure, comprising:
a substrate body;
a metal layer formed on a surface of the substrate body;
an insulating layer formed on the surface of the substrate body and having at least an opening exposing the metal layer; and
at least a die attach area defined on the surface of the substrate body corresponding in position to the opening for a semiconductor chip to be disposed thereon, wherein the die attach area covers whole the opening or the metal layer is formed within the die attach area.

2. The substrate structure of claim 1, wherein the die attach area is located at the center of the opening.

3. The substrate structure of claim 1, wherein a dielectric layer formed on the surface of the substrate body is exposed from the opening.

4. The substrate structure of claim 1, wherein the metal layer comprises circuits and heat dissipation pads.

5. A semiconductor package, comprising:
a substrate body;
a metal layer formed on a surface of the substrate body;
an insulating layer formed on the surface of the substrate body and having at least an opening exposing the metal layer; and
at least a semiconductor chip disposed on the metal layer corresponding in position to the opening, wherein a projection of the semiconductor chip on the surface of the substrate body covers whole the opening or the metal layer is formed within the projection of the semiconductor chip on the surface of the substrate body.

6. The semiconductor package of claim 5, further comprising an encapsulant formed on the surface of the substrate body for encapsulating the semiconductor chip.

7. The semiconductor package of claim 5, wherein the semiconductor chip is disposed on the metal layer in a flip-chip manner.

8. The semiconductor package of claim 5, wherein the metal layer is made of copper.

9. The semiconductor package of claim 5, further comprising a plurality of conductive pads formed on another surface of the substrate body.

10. The semiconductor package of claim 9, further comprising a plurality of solder balls formed on the conductive pads, respectively.

11. The semiconductor package of claim 5, wherein the semiconductor chip is located at the center of the opening.

12. The semiconductor package of claim 5, wherein a dielectric layer formed on the surface of the substrate body is exposed from the opening.

13. The semiconductor package of claim 5, wherein the metal layer comprises circuits and heat dissipation pads.
